(19) United States
(12) Patent Application Publication
(10) Pub. No.: US 2025/0105101 A1
(43) Pub. Date: Mar. 27, 2025

(54) ELECTRONIC PACKAGE FOR HIGH VOLTAGE APPLICATIONS

(71) Applicant: Navitas Semiconductor Limited, Dublin (IE)

(72) Inventor: Oseob Jeon, Seoul (KR)

(73) Assignee: Navitas Semiconductor Limited, Dublin (IE)

(21) Appl. No.: 18/893,668

(22) Filed: Sep. 23, 2024

Related U.S. Application Data
(60) Provisional application No. 63/584,487, filed on Sep. 21, 2023.

(51) Int. Cl. H01L 23/492; H01L 23/367; H01L 23/498

(52) U.S. Cl. CPC H01L 23/492; H01L 23/367; H01L 23/49811

(57) ABSTRACT

An electronic device includes a body having a first side opposite and spaced apart from a second side, the body including third and fourth sides extending between the first and second sides and further including a top surface that extends between the first, second, third, and fourth sides, and wherein a central axis extends from the first side to the second side. Each of the third and fourth sides have a plurality of first extending portions and a plurality of second extending portions, each first extending portion extending a first distance from the central axis and each second extending portion extending a second distance from the central axis, wherein the first distance is greater than the second distance. The body defines first and second grooves that each extend between the first and second sides.

### CROSS-REFERENCE TO RELATED APPLICATIONS

This application claims priority to U.S. provisional patent application Ser. No. 63/584,487, for “POWER DEVICES WITH IMPROVED CREEPAGE AND CLEARANCE” filed on Sep. 21, 2023, the contents of which are incorporated herein by reference in their entirety for all purposes.

### FIELD

The present invention relates generally to electronic devices and in particular to electronic devices with features for high voltage applications.

### BACKGROUND

Electronic packages can include pin connectors for external electrical connections. To meet the needs of high voltage applications, some electronic packages may require an increase in package size, which can result in higher packing costs and a larger volume of the final product. There is a need for a high-voltage electronic package that has improved creepage and clearance performance in a compact volume.

### SUMMARY

In some embodiments an electronic device comprises a body having a first side opposite and spaced apart from a second side, the body including the third and fourth sides extending between the first and second sides and further including a top surface that extends between the first, second, third, and fourth sides, and a central axis extends from the first side to the second side. Each of the third and fourth sides have a plurality of first extending portions and a plurality of second extending portions, each first extending portion extending a first distance from the central axis and each second extending portion extending a second distance from the central axis, wherein the first distance is greater than the second distance. The body defines first and second grooves disposed in the top surface that each extend between the first and second sides, the first and second grooves each have a groove base surface that is recessed from the top surface, the top surface defines a base plate aperture, and a base plate positioned within the base plate aperture; and the first groove is positioned between the third side and the base plate aperture and the second groove is positioned between the fourth side and the base plate aperture.

In various embodiments the base plate is coplanar with the top surface or extends above the top surface. In some embodiments the power module further comprises a heatsink attached to the top surface and thermally coupled to the base plate. In various embodiments the body further includes a bottom surface positioned opposite the top surface, wherein the body has a first thickness defined between the top surface and the bottom surface and wherein the first and second extending portions have a second thickness that is less than the first thickness. In some embodiments the second extending portions of the plurality of second extending portions disposed on the third side are directly opposite the first extending portions of the plurality of first extending portions disposed on the fourth side. In various embodiments, the body defines a plurality of recesses, wherein a respective recess is defined between each respective first extending portion and each adjacent respective second extending portion. In some embodiments each recess of the plurality of recesses has a recessed surface positioned a third distance from the central axis and wherein the second distance is greater than the third distance. In various embodiments the first extending portions, the second extending portions, and the plurality of recesses have coplanar surfaces that are recessed from the top surface. In some embodiments each of the plurality of first extending portions include a first set of electrical pins and each of the plurality of second extending portions include a second set of electrical pins.

In various embodiments an electronic device comprises a body having a first side opposite and spaced apart from a second side, the body including third and fourth sides extending between the first and second sides wherein a central axis extends from the first side to the second side; and each of the third and fourth sides have a plurality of first extending portions and a plurality of second extending portions, each first extending portion extending a first distance from the central axis and each second extending portion extending a second distance from the central axis, wherein the first distance is greater than the second distance. In some embodiments the body includes a top surface that extends between the first, second, third, and fourth sides, and wherein the top surface defines a base plate aperture, the electronic device further comprising a base plate positioned within the base plate aperture, wherein the base plate is coplanar with the top surface or extends above the top surface. In various embodiments the second extending portions of the plurality of second extending portions disposed on the third side are directly opposite the first extending portions of the plurality of first extending portions disposed on the fourth side. In some embodiments the body includes a top surface that extends between the first, second, third, and fourth sides, the body further defining a plurality of recesses, wherein a respective recess is between each respective first extending portion of the plurality of first extending portions and each respective adjacent second extending portion of the plurality of second extending portions. In various embodiments each recess of the plurality of recesses has a recessed surface positioned a third distance from the central axis and wherein the second distance is greater than the third distance. In some embodiments the plurality of first extending portions, the plurality of second extending portions, and the plurality of recesses have coplanar surfaces that are recessed from the top surface.

In various embodiments each of the plurality of first extending portions include a first set of electrical pins and each of the plurality of second extending portions include a second set of electrical pins. In some embodiments an electronic device comprises a body having a first side opposite and spaced apart from a second side, the body including third and fourth sides extending between the first and second sides and further including a top surface extend between the first, second, third, and fourth sides, and wherein a central axis extends from the first side to the second side; wherein the body defines first and second grooves along the top surface that each extend between the first and second sides, the first and second grooves each having a groove base surface that is recessed from the top surface; wherein the top surface defines a base plate aperture; and a base plate positioned within the base plate aperture; and wherein the first groove is positioned between the third side and the base plate aperture and wherein the second groove is positioned between the fourth side and the base plate aperture. In various embodiments the base plate is coplanar with the top surface or extends above the top surface. In some embodiments the electronic device further comprises a heatsink attached to the top surface and thermally coupled to the base plate. In various embodiments the body includes a plurality of electrical pins.

### BRIEF DESCRIPTION OF THE DRAWINGS

FIG. 1A is a top view schematic of an electronic package according to some aspects of the present application;

FIG. 1B is a side view schematic of an electronic package according to some aspects of the present application;

FIG. 1C is a partial top view of an electronic package that illustrates inter pin creepage and clearance between adjacent pin pairs;

FIG. 1D is a partial side view of an electronic package that illustrates multiple paths for base plate creepage between a base plate and electrical pins;

FIG. 2A is a top view schematic of an electronic package system that includes an electronic package with an attached heat sink according to some aspects of the present application; and

FIG. 2B is a side view schematic of an electronic package with an attached heat sink according to some aspects of the present application.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

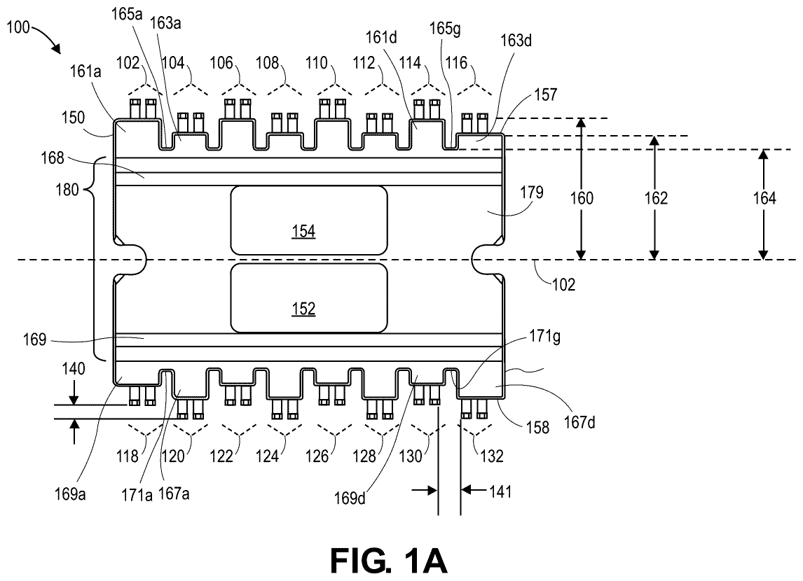

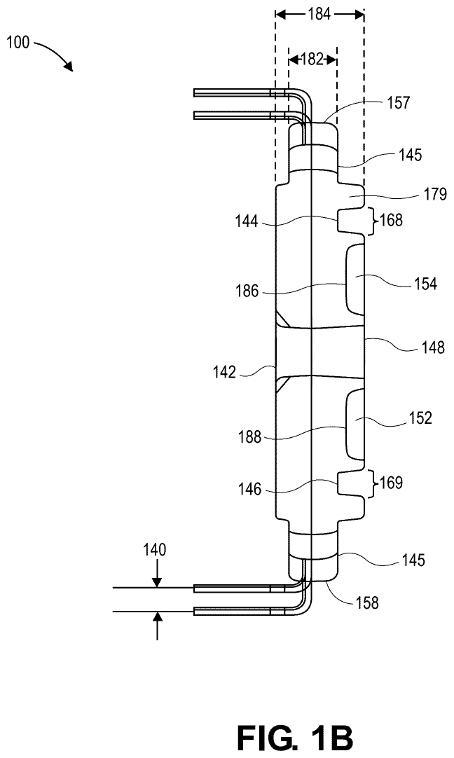

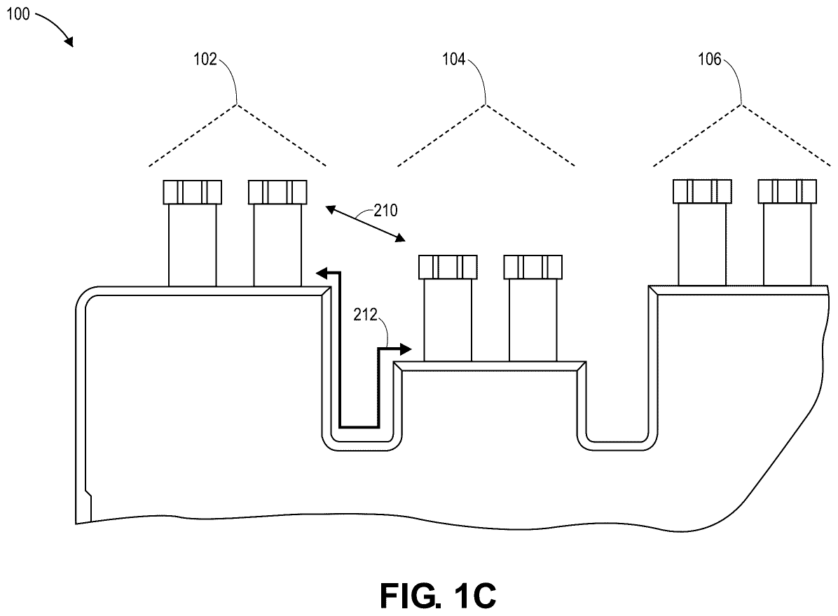

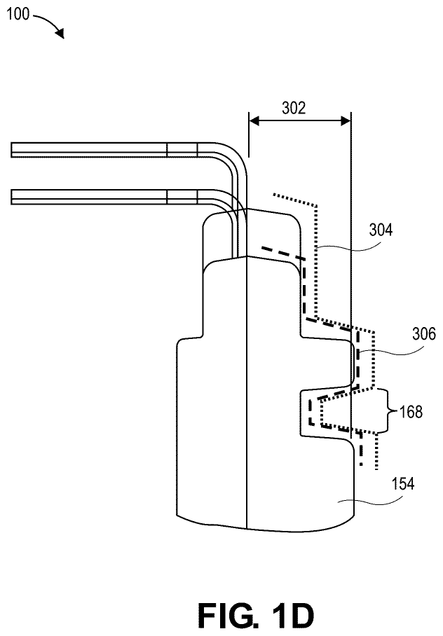

FIG. 1A is a top view of an electronic package 100 according to some aspects of the present application. The electronic package 100 may be or include any of the components, features, or characteristics of any of the electronic packages described in the present disclosure. Electronic package 100 has a body 179 that has a first side 150 opposite and spaced apart from a second side 156. Additionally, the body 179 has a third side 157 and a fourth side 158 extending between the first side 150 and the second side 156. The body 179 further includes a top surface 148 opposite a bottom surface (not shown in FIG. 1A). The top surface 148 and the bottom surface extend between the first 150, second 156, third 157, and fourth 158 sides. A central axis 102 of the top surface 148 extends from the first side 150 to the second side 156.

The third 157 and the fourth 158 sides each can include a plurality of first extending portions and a plurality of second extending portions. For example, the third side 157 can include first extending portions 161a-161d and second extending portions 163a-163d. Although the third side 157 is depicted in FIG. 1A with four first extending portions, for simplicity only first extending portion 161a and first extending portion 161d are shown with element numbers. Likewise, the third side 157 is depicted in FIG. 1A with four second extending portions 163, for simplicity only second extending portion 163a and second extending portion 163d are shown with element numbers. The third side 157 can include any number of first and second extending portions, including one of each.

The fourth side 158 can include first extending portions 167a-167d and second extending portions 169a-169d. Although the fourth side 158 is depicted in FIG. 1A with four first extending portions, for simplicity only first extending portion 167a and first extending portion 167d are shown with element numbers. Likewise, the fourth side 158 is depicted in FIG. 1A with four second extending portions, for simplicity only second extending portion 169a and second extending portion 169d are shown with element numbers. The fourth side 158 can include any number of first and second extending portions, including one of each.

Each of the first extending portions can extend a first distance 160 from the central axis 102 and each of the second extending portions can extend a second distance 162 from the central axis 102. The first distance 160 can be greater than the second distance 162. Recesses in each of the third 157 and fourth sides 158 can be defined between each of the first and each of the second extending portions. Each recess can have a recessed surface that extends a third distance 164 from the central axis 102. The third distance 164 can be less than the second distance 162.

For example, a recess defined between first extending portion 161a and second extending portion 163a can have recessed surface 165a. The recessed surface 165a can be closer to the central axis 102 than both second extending portion 163a and first extending portion 161a. As another example, a recess defined between first extending portion 161d and second extending portion 163d can have a recessed surface 165g. Although seven recess surfaces are shown on the third side 157 of the body 179, the third side 157 can include any number of recess surfaces including a single recess surface. Similarly, a recess defined between first extending portion 167a and second extending portion 169a can have recessed surface 171a. The recessed surface 171a can be closer to the central axis 102 than both second extending portion 163b and first extending portion 161b. Additionally, a recess defined between first extending portion 167d and second extending portion 169d can have recessed surface 171g. Although seven recess surfaces are shown on the fourth side 158 of the body 179, the fourth side 158 can include any number of recess surfaces including a single recess surface. The first extending portions, second extending portions, and recesses can each have coplanar surfaces that are recessed from the top surface. In FIG. 1A, each of the first extending portions (e.g., first extending portion 167a) of the fourth side 158 are directly opposite a second extending portion (e.g., second extending portion 163a) of the third side 157. In other examples, the first extending portions of the fourth side 158 may be directly opposite the first extending portions of the third side 157.

The top surface can define a first base plate aperture 186 and a second base plate aperture 188 that are each formed in the body 179. The first base plate aperture 186 can be positioned between the central axis 102 and the third surface 157. The second base plate aperture 188 can be positioned between the central axis 102 and the fourth surface 158. A first base plate 154 can be positioned in the first base plate aperture 186 and a second base plate 152 can be positioned in the second base plate aperture 188. The first 154 and second base 152 plates can be exposed at the top surface 148 and may be at a voltage potential or may be electrically isolated. Both the first base plate 154 and the second base plate 152 can be thermally coupled to a heatsink or cold plate that can be attached to the top surface 148 of the body 179 and arranged to conduct thermal energy from one or more electronic devices (e.g., power transistors) disposed within the body 179. The heatsink or cold plate may be electrically coupled to ground or a voltage potential.

The top surface 148 of the body 179 can further define one or more grooves, such as first and second grooves, 168, 169, respectively. The first and second grooves, 168, 169, respectively, can extend from the first side 150 to the second side 156, or may only extend a portion of the length of the body. The first groove 168 can be positioned between the first base plate aperture 186 and the third side 157. The second groove 169 can be positioned between the second base plate aperture 188 and the fourth side 158. The first and second grooves, 168, 169, respectively, can each have a groove base surface that is recessed from the top surface 148. Although two grooves are depicted in FIG. 1A, the electronic package 100 can include any number of grooves including a single groove. The body 179 can include a central portion 180. The central portion 180 can include the first and second grooves, 168, 169, respectively, and the first and second base plates, 154, 152, respectively.

A first set of electrical pins can extend from each of the first extending portions and a second set of electrical pins can extend from each of the second extending portions. For example, each of the first extending portions (161a-161d) of the third side 157 can include respective first electrical pin pairs, 102, 106, 110, and 114, respectively, and each of the second extending portions (163a-163d) of the third side can include respective second electrical pin pairs, 104, 108, 112, and 116, respectively. Similarly, each of the first extending portions (167a-167d) of the third side 158 can include respective first electrical pin pairs, 120, 124, 128, and 132, respectively, and each of the second extending portions (169a-169d) of the third side can include respective second electrical pin pairs, 118, 122, 126, and 130, respectively. The first extending pin pairs can be referred to as outer pin pairs and the second extending pin pairs can be referred to as inner pin pairs. While the first and second set of electrical pins are shown as pairs of pins in FIG. 1A, the first and second sets of electrical pins can include any number of electrical pins including a single electrical pin. The first extending pin pairs can extend further from the central axis 102 than the second extending pin pairs by an extension distance 140. The extension distance 140 between adjacent pin pairs can provide an increased distance between adjacent pin pairs resulting in an increased creepage and clearance distance between adjacent pins as compared to a device with all pins in a single row. The increased creepage and clearance distance can enable the electronic package 100 to operate at higher voltages. A first offset distance 141 defines a distance parallel to the third 157 and fourth sides 158 between adjacent pin pairs. The recesses between each first and second extending portions can increase creepage distance between each pin pair and an adjacent pin pair. The creepage distance can be defined as a shortest path length across an exterior surface of the device between two pins. A larger creepage distance enables the electronic package to operate at higher voltage potentials. A second offset distance 140 defines an additional distance between adjacent pin pairs. The second offset distance 140 is perpendicular to the first offset distance 141. In some embodiments the electronic package 100 is between 40 and 50 mm in length and between 30 and 40 mm in width, however other embodiments may have larger or smaller dimensions.

In some embodiments, body 179 may be made from a dielectric material including any suitable polymer, ceramic or combination thereof. Pins may be made from any suitable electrically conductive metal, including copper, and alloys thereof. Electronic package 100 may include one or more active and/or passive electrical components, including but not limited to, silicon, gallium nitride, silicon carbide, gallium arsenide or other semiconductor devices including power transistors. In some embodiments first and second baseplates 152, 154, respectively are each thermally coupled to one or more semiconductor devices, including power transistors.

FIG. 1B is a side view of electronic package 100. The electronic package 100 has a body 179 that has a top surface 148 opposite a bottom surface 142. The top surface 148 can define a plurality of grooves, such as first groove 168 and second groove 169. The first groove 168 can have a first groove base surface 144 that is recessed from the top surface 148. Similarly, the second groove 169 can have a second groove base surface 146 that is recessed from the top surface 148.

The top surface 148 can further define a first base plate aperture 186 and a second base plate aperture 188. A first base plate 154 can be positioned in the first base plate aperture 186 and a second base plate 152 can be positioned in the second base plate aperture 188. The first base plate 154 can include a surface that is coplanar with the top surface 148 or that can extend above the top surface 148. Similarly, the second base plate 152 can include a surface that is coplanar with the top surface 148 or that can extend above the top surface 148. The plurality of grooves can increase the creepage distance from the base plates to the electrical pins.

The body 179 can further include third 157 and fourth 158 sides. As depicted in FIG. 1A, the third 157 and the fourth 158 sides each can include a plurality of first extending portions, a plurality of second extending portions, and recesses. The first extending portions, second extending portions, and recesses can each have a coplanar surface 145 that is recessed from the top surface 148. The body 179 can include a first thickness 184 and a second thickness 182. The first thickness 184 can extend from the top surface 148 to the bottom surface 142. The second thickness 182 can be associated with the first and second extending portions. The first thickness 184 can be greater than the second thickness 182. An offset distance 140 can provide distance between adjacent pin pairs.

FIG. 1C is a partial top view of electronic package 100 that illustrates inter-pin creepage distance 212 and clearance distance 210 between adjacent pin pairs. The electronic package 100 may be or include any of the components, features, or characteristics of any of the electronic packages described in the present disclosure. FIG. 1C shows a magnified view of a corner of electronic package 100. Pin pairs 102, 104 and 106 are shown. The clearance distance between adjacent pins is shown as feature 210, while the creepage distance between adjacent pin pairs is shown as path 212. In this example the clearance distance 210 is approximately 2.5 mm while the creepage distance between adjacent pin pairs is approximately 7.5 mm, however in other embodiments the distances may be smaller or greater.

FIG. 1D is a magnified partial side view of electronic package 100 that illustrates multiple creepage paths between base plate 154 and electrical pins. The baseplate creepage distance can be described as surface distance from the closest pin pair to the baseplate 154. Creepage distance from inner pin pairs to base plate is shown as a first path 306. The creepage distance from outer pin pairs to base plate 154 is shown as a second path 304. The creepage distances can be increased by positioning the pins towards the bottom surface of the body and by forming one or more grooves 168 in the top surface of the body. While one groove 168 is shown in FIG. 1D, two, three, four or more grooves can be disposed between the pins and the baseplate to further increase the creepage distance. The groove 168 increases a surface distance from each pin pair to the baseplates. Although creepage paths are shown for just one edge having electrical pins of the electronic package 100, creepage distance 306 can be the same as a creepage distance to the inner pin pairs for other edges having electrical pins. Similarly, creepage distance 304 can be the same as a creepage distance to the outer pin pairs for other edges with electrical pins. In this example, the creepage path 304 is approximately 15.5 mm and the creepage path 306 is approximately 14 mm. In other embodiments the creepage distances may be shorter or longer depending on the dimensions of the module. Additionally, clearance distance 302 between electrical pins and a heat sink that would extend over the electrical pins is also illustrated in FIG. 1D.

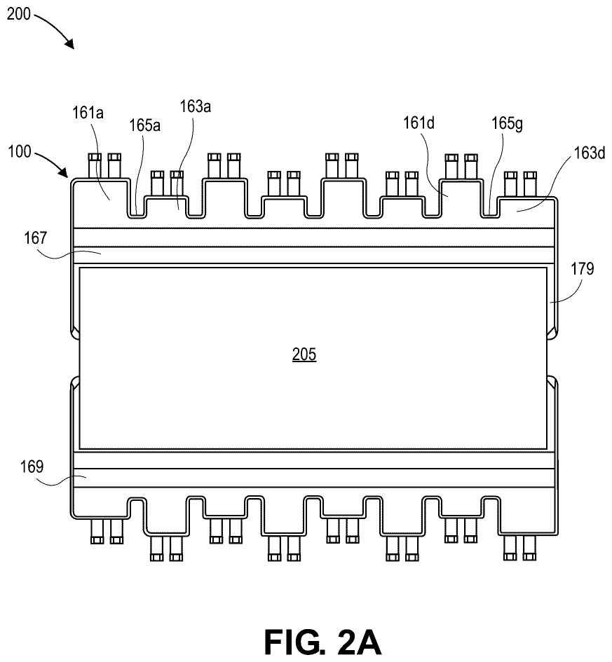

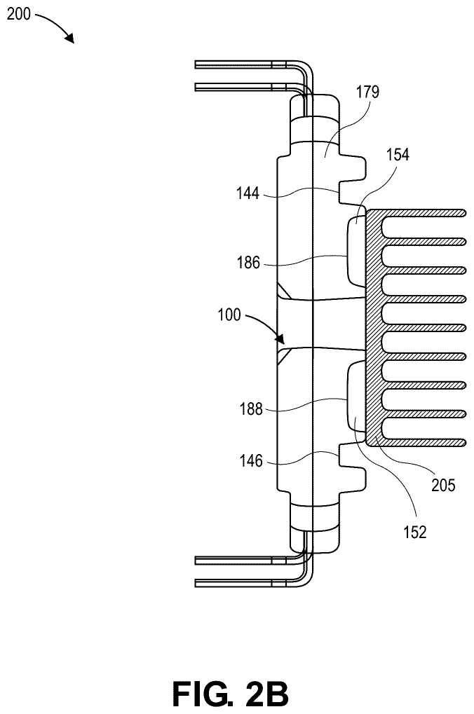

FIG. 2A is a top view of a electronic package system 200 that includes electronic package 100 with an attached heat sink 205, according to some aspects of the present application. As shown in FIG. 2A, body 179 of electronic package 100 includes first groove 168 and second groove 169. The first and second grooves 168, 169, respectively, can increase creepage from the pins to the heatsink 205. In some embodiments, the heat sink 205 can be replaced by an active or passive heat exchanger. The body 179 can further include first extending portions (e.g., first extending portions 161a-161d), second extending portions (e.g., second extending portions 163a-163d), and recessed surfaces (e.g., recessed surfaces 165a-165g).

FIG. 2B is a side view of electronic package system 200 that includes a electronic package 100 with an attached heat sink 205. As shown in FIG. 2B, the electronic package 100 has a body 179 that includes a first groove with a first grove surface 144 and a second groove with a second groove surface 146. As described above, grooves of the electronic package 100 can increase creepage to the heatsink 405 and/or to first and second baseplates 154, 152, respectively. In some embodiments, the heat sink 205 can have a plurality of pins or fins to radiate heat, while in other embodiments the heat sink 205 can be liquid-cooled. The body 179 can further include a first base plate aperture 186 and a second base plate aperture 188. A first base plate 154 can be positioned in the first base plate aperture 186 and a second base plate 152 can be positioned in the second base plate aperture 188.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. An electronic device comprising:
a body having a first side opposite and spaced apart from a second side, the body including third and fourth sides extending between the first and second sides and further including a top surface that extends between the first, second, third, and fourth sides, and wherein a central axis extends from the first side to the second side;
wherein each of the third and fourth sides have a plurality of first extending portions and a plurality of second extending portions, each first extending portion extending a first distance from the central axis and each second extending portion extending a second distance from the central axis, wherein the first distance is greater than the second distance;
wherein the body defines first and second grooves disposed in the top surface that each extend between the first and second sides, the first and second grooves each having a groove base surface that is recessed from the top surface;
wherein the top surface defines a base plate aperture; and
a base plate positioned within the base plate aperture; and
wherein the first groove is positioned between the third side and the base plate aperture and wherein the second groove is positioned between the fourth side and the base plate aperture.

2. The electronic device of claim 1, wherein the base plate is coplanar with the top surface or extends above the top surface.

3. The electronic device of claim 1, further comprising a heatsink attached to the top surface and thermally coupled to the base plate.

4. The electronic device of claim 1, wherein the body further includes a bottom surface positioned opposite the top surface, wherein the body has a first thickness defined between the top and the bottom surface and wherein the first and second extending portions have a second thickness that is less than the first thickness.

5. The electronic device of claim 1, wherein the second extending portions of the plurality of second extending portions disposed on the third side are directly opposite the first extending portions of the plurality of first extending portions disposed on the fourth side.

6. The electronic device of claim 1, wherein the body defines a plurality of recesses, wherein a respective recess is defined between each respective first extending portion and each adjacent respective second extending portion.

7. The electronic device of claim 6, wherein each recess of the plurality of recesses has a recessed surface positioned a third distance from the central axis and wherein the second distance is greater than the third distance.

8. The electronic device of claim 6, wherein the first extending portions, the second extending portions, and the plurality of recesses have coplanar surfaces that are recessed from the top surface.

9. The electronic device of claim 1, wherein each of the plurality of first extending portions include a first set of electrical pins and each of the plurality of second extending portions include a second set of electrical pins.

10. An electronic device comprising:
a body having a first side opposite and spaced apart from a second side, the body including third and fourth sides extending between the first and second sides wherein a central axis extends from the first side to the second side; and
wherein each of the third and fourth sides have a plurality of first extending portions and a plurality of second extending portions, each first extending portion extending a first distance from the central axis and each second extending portion extending a second distance from the central axis, wherein the first distance is greater than the second distance.

11. The electronic device of claim 10, wherein the body includes a top surface that extends between the first, second, third, and fourth sides, and wherein the top surface defines a base plate aperture, the electronic device further comprising a base plate positioned within the base plate aperture, wherein the base plate is coplanar with the top surface or extends above the top surface.

12. The electronic device of claim 10, wherein the second extending portions of the plurality of second extending portions disposed on the third side are directly opposite the first extending portions of the plurality of first extending portions disposed on the fourth side.

13. The electronic device of claim 10, wherein the body includes a top surface that extends between the first, second, third, and fourth sides, the body further defining a plurality of recesses, wherein a respective recess is defined between each respective first extending portion of the plurality of first extending portions and each respective adjacent second extending portion of the plurality of second extending portions.

14. The electronic device of claim 13, wherein each recess of the plurality of recesses has a recessed surface positioned a third distance from the central axis and wherein the second distance is greater than the third distance.

15. The electronic device of claim 13, wherein the plurality of first extending portions, the plurality of second extending portions, and the plurality of recesses have coplanar surfaces that are recessed from the top surface.

16. The electronic device of claim 10, wherein each of the plurality of first extending portions include a first set of electrical pins and each of the plurality of second extending portions include a second set of electrical pins.

17. An electronic device comprising:
a body having a first side opposite and spaced apart from a second side, the body including third and fourth sides extending between the first and second sides and further including a top surface extend between the first, second, third, and fourth sides, and wherein a central axis extends from the first side to the second side;
wherein the body defines first and second grooves along the top surface that each extend between the first and second sides, the first and second grooves each having a groove base surface that is recessed from the top surface;
wherein the top surface defines a base plate aperture; and
a base plate positioned within the base plate aperture; and
wherein the first groove is positioned between the third side and the base plate aperture and wherein the second groove is positioned between the fourth side and the base plate aperture.

18. The electronic device of claim 17, wherein the base plate is coplanar with the top surface or extends above the top surface.

19. The electronic device of claim 17, further comprising a heatsink attached to the top surface and thermally coupled to the base plate.

20. The electronic device of claim 17, wherein the body includes a plurality of electrical pins.
